(19) United States
(12) Patent Application Publication
(10) Pub. No.: US 2012/0305300 A1
(43) Pub. Date: Dec. 6, 2012

(54) METHODS FOR MANUFACTURING AN ELECTRIC CONTACT PAD AND ELECTRIC CONTACT

(75) Inventors: Christine Bourda, Mainvilliers (FR); Gilles Rolland, Orsay (FR); Michel Jeandin, Paris (FR)

(73) Assignee: METALOR TECHNOLOGIES INTERNATIONAL SA, Neuchatel (CH)

(21) Appl. No.: 13/516,807

(22) PCT Filed: Dec. 16, 2010
(86) PCT No.: PCT/EP2010/069885

§ 371 Date: Aug. 8, 2012

(30) Foreign Application Priority Data
Dec. 18, 2009 (EP) 09179852.0

(51) Int. Cl. H05K 1/11; H01R 43/20; B05D 1/18; B05D 3/12; B05D 5/12; C23C 16/06

(52) U.S. Cl. 174/257; 174/261; 427/96.1; 427/96.8; 427/99.5; 427/97.1; 427/99.2; 29/876

(57) ABSTRACT

A method for manufacturing an electrical contact pad, including a pad mounting and at least one contact layer, and a method for manufacturing an electrical contact, including a contact mounting and at least one contact layer are described. The methods include a step of depositing, via cold gas dynamic spraying, a first powder onto the pad or contact mounting so as to form the contact layer, the first powder containing at least particles including grains made of at least one refractive material, the grains being built into a matrix made of conductive metal selected from among silver or copper. The pads and the electrical contacts obtained in the respective manufacturing methods are also described.

### TECHNICAL FIELD

The present invention relates to the field of electric contacts. It more particularly relates to a method for manufacturing an electric contact pad and a method for manufacturing an electric contact, as well as to an electric contact pad and an electric contact which may be obtained by their respective manufacturing method.

### STATE OF THE ART

So-called “low voltage” electric contacts, i.e. for which the operating range is approximately located between 10 and 1,000 V and between 1 and 10,000 A, are generally used in the domestic, industrial and automotive fields, both in DC and AC, for switches, relays, contactors and circuit breakers, etc.

The electric contacts are made from materials which have to meet the three following requirements:
a low and stable contact resistance in order to avoid excessive heating when the current flows through it;
good resistance to welding in the presence of an electric arc; and
low erosion under the effect of the arc.

In order to meet these partly contradictory requirements, a solution consists of using, in order to make the pad, pseudo-alloys including a silver or copper matrix and, inserted in this matrix, a fraction consisting of about 10% to 50% by volume of refractory particles (for example Ni, C, W, WC, CdO, SnO2) with a size generally comprised between 1 and 5 μm. The thereby obtained material better withstands the energy released by the electric arc.

In a conventional way known to one skilled in the art, the pad may be obtained from powders, by compaction-sintering or compaction-sintering-extrusion-lamination-cutting. The pad is then assembled on a suitable contact support, a very good conductor of electricity and of heat, in order to obtain an electric contact. The assembling of the pad on the contact support may be accomplished by welding, brazing or riveting for example.

More particularly, the contact support is traditionally copper. As the pad is made to be resistant to welding, the assembling of the pad on the copper by welding is difficult. It is therefore necessary to add onto the pad, a silver binding layer for example.

These conventional methods include many operations which cause a high manufacturing cost.

Moreover, it is very difficult to assemble the pad by welding or brazing on an aluminium contact support, since this requires heating of the support to a temperature close to its melting point.

An object of the present invention is therefore to overcome these drawbacks, by proposing a method for manufacturing an electric contact pad and methods for manufacturing an electric contact with which known methods may be simplified by reducing the number of operations.

Another object of the present invention is to propose a method for manufacturing an electric contact with which aluminium may be more easily used as a material for an electric contact support.

### DISCLOSURE OF THE INVENTION

For this purpose, and according to a first aspect of the present invention, a method for manufacturing at least one electric contact pad comprising a pad support and at least one contact layer is proposed, said method comprising a step for depositing, by cold gas dynamic spraying, a first powder on said pad support in order to form said contact layer, said first powder containing at least particles comprising grains of at least one refractory material incorporated into a matrix based on a conducting metal selected from silver or copper.

According to another aspect, the invention relates to a method for manufacturing an electric contact comprising a contact support and at least one pad, said method comprising:
a step for manufacturing said pad with the method for manufacturing a pad as defined above, and
a step for assembling said pad onto said contact support.

According to another aspect, the invention relates to a method for manufacturing an electric contact comprising a contact support and at least one contact layer, said method comprising a step for depositing, by cold gas dynamic spraying, a first powder on said contact support in order to form said contact layer, said first powder containing at least particles comprising grains of at least one refractory material incorporated into a matrix based on a conducting metal selected from silver or copper.

The present invention also relates to an electric contact pad which may be obtained by the method for manufacturing an electric contact pad as defined above.

The present invention also relates to an electric contact which may be obtained by either one of the methods for manufacturing an electric contact as defined above.

### SHORT DESCRIPTION OF THE DRAWINGS

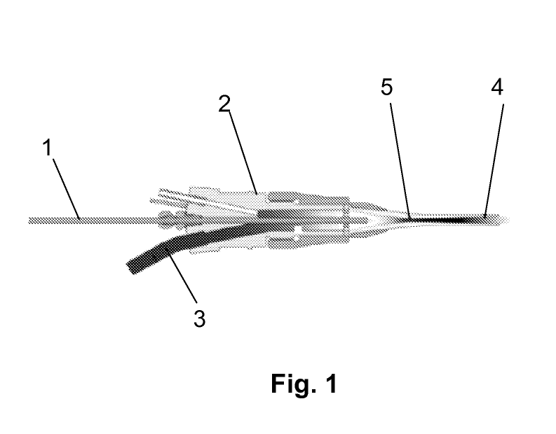

The invention will be better understood upon reading the following description, made with reference to the appended FIG. 1, schematically illustrating a cold spraying gun.

### EMBODIMENTS OF THE INVENTION

The present invention relates to a method for manufacturing at least one electric contact pad comprising a pad support and at least one contact layer as well as to a similar method applied to the manufacturing of at least one electric contact comprising a contact support and at least one contact layer. The methods according to the invention are first of all distinguished in that they use cold gas dynamic spraying technique in order to deposit a first powder on said pad support or on said contact support in order to form said contact layer.

This technique for depositing a powder by cold gas dynamic spraying, also called a <<cold spray>> technique, is characterized, unlike the other thermal projection methods, by a low spraying temperature and a high spraying velocity of the powder particles which may range up to Mach 5. Unlike plasma or HVOF methods wherein the powder particles are melted before impacting the substrate, the cold spray method, because a spray gas temperature does not generally exceed 600° C., does not cause any melting of the particles which therefore remain in the solid state during the whole spraying duration. Upon impacting the substrate, the particles plastically deform and agglomerate in order to form a deposit. The benefit of the cold spray method as compared with plasma spraying for example, is not to heat up too much the particles making up the deposit as well as the support, whence low oxidation which is favorable for obtaining better electric conductivity and good cohesion. The cold spray method is for example described in patent EP 0 484 533.

In practice, the principle of the cold spray method may be described in the following way with reference to FIG. 1. The powder 1, with a grain size ideally comprised between 5 and 50 μm, is conveyed under pressure to the spraying nozzle 2 via a carrier gas, generally of the same nature as the propellant gas 3. Provision of kinetic energy to the particles is carried out via a carrier gas which may be heated between 200° C. and 650° C. in order to increase the expansion and therefore its velocity. The powder+carrier gas mixture is brought to a supersonic velocity at the nozzle outlet 4 by means of its particular shape (Laval nozzle 5) which brings the mixture at the outlet to a greatly supersonic velocity. Although the temperature of the gases may seem to be high at first sight, the divergent portion of the nozzle 5 causes expansion of the gases and therefore a lowering of the temperature which is non-negligible (from 650° C. to 260° C.). The particles of powders which moreover have an extremely limited dwelling time in the flow of hot gases, remain in every case in a solid or slightly viscous state (surface heating).

It may be considered that cold spray deposits form in the following way:
stripping of the surface of the substrate: is used as sanding for cleaning the support (for example removal of surface oxides), in order to then allow good adhesion of the first layer
forming the first layer on the substrate
building the deposit and densifying the layers.

In the cold spray method, it is possible to control seven parameters, i.e.:
the nature of the propellant gas (air, nitrogen, helium and mixtures thereof)
the temperature of the propellant gas
the geometry of the nozzle
the introduction pressure of the gases in the spraying nozzle (subsequent expansion in the nozzle)
characteristics intrinsic to the powder (nature, shape, grain size, oxidation state)
the spraying distance (which influences the impact velocity on the substrate)
the projection angle.

The main parameter influencing the quality of the obtained deposits is the spraying velocity of the particles. Indeed, a too low velocity causes poor cohesion between the particles of powders.

Another important parameter to be considered is the nature of the powder used.

The methods according to the invention are also distinguished in that the deposited powder for forming the contact layer of the pad or of the electric contact, called a first powder subsequently, contains at least particles comprising grains of at least one refractory material incorporated into a matrix based on a conducting metal selected from silver or copper.

The first powder is therefore prepared prior to the deposition. More particularly, the particles comprising the grains of at least one refractory material incorporated into the conducting metal matrix are obtained from a method selected from the group comprising physical vapor deposition methods (PVD), chemical vapor deposition methods (CVD), electroless methods, chemical precipitation on suspended particles.

The particles obtained by chemical precipitation on suspended particles, a method described in patents U.S. Pat. No. 5,846,288 and U.S. Pat. No. 5,963,772 for example, are more preferred. Indeed, these particles have a spongeous structure with <<percolating>> porosity, i.e. communicating with each other, whence great deformability so as not to rebound during the cold spray deposition.

Advantageously, the refractory metal may be selected from the group comprising CdO, CuO, SnO₂, ZnO, Bi₂O₃, C, WC, MgO, In₂O₃, as well as Ni, Fe, Mo, Zr, W or oxides thereof.

The first powder may contain between 2% and 50%, preferably between 5% and 40%, and more preferentially between 10% and 40% by volume of grains of refractory material based on the total volume of the first powder.

The conducting metal present in the contact layer of the pad or of the electric contact may make up 100% of the matrix comprising the grains of the refractory material or a lower amount. In the latter case, the first powder further contains pure metal particles corresponding to the conducting metal of the matrix containing the grains of refractory material, representing the remainder of conducting metal present in the contact layer.

Further, the first powder may also contain at least one doping agent.

According to a first possibility, particles comprising grains of at least one first doping agent are incorporated into a metal matrix, the metal of which corresponds to the conducting metal of the matrix containing the grains of refractory material. These particles are prepared in the same way as the particles comprising the grains of refractory material incorporated into the matrix of conducting metal, and are then mixed with said particles comprising the grains of refractory material incorporated into the conducting metal matrix and optionally with the pure metal particles in order to form the first powder.

According to a second possibility, at least one second doping agent is incorporated with grains of refractory material in order to combine them in their conducting metal matrix.

According to a third possibility, at least one third doping agent is introduced into the matrix containing the grains of refractory material.

Preferably, the first, second and third doping agent is a metal or an oxide of this metal, said metal being selected from the group comprising Bi, Mo, W, Re, In and Cu.

Preferably, the size of the particles of the first powder is comprised between 10 μm and 300 μm.

At the end of the methods according to the invention, it is further possible to provide a step for shaping the pad or the contact, at its surface. This shaping may be accomplished for example by plastic deformation (stamping, heading, rolling), material removal (milling, planing, grinding) or possibly with both.

According to a first alternative of the invention, with the method for manufacturing an electric contact, an electric contact may be obtained directly, comprising a contact support and at least one contact layer as defined above.

The contact support is a conducting support, preferentially consisting of a metal which is a very good conductor of electricity and of heat. Typically, the contact support may be made in a material selected from the group comprising copper, aluminium, copper alloys, aluminium alloys, or further a composite consisting of a conducting metal and of a metal with a high elastic limit, for example copper on steel.

The contact support may be coated with a galvanic silver or copper deposit.

The contact support may appear as precut individual parts. The contact support may also appear as a continuous strip. In this case, the method may further comprise a step for cutting out said strip in order to form electric contacts. If the contact support appears as a strip, the contact layer may be deposited on the contact support by cold spray deposition, according to the invention, so as to form discrete contact points or at least one continuous track.

In this alternative, the method for manufacturing an electric contact according to the invention allows an electric contact to be obtained directly, in few operations, unlike the conventional methods for manufacturing electric contacts.

The deposition method by cold spray also has the advantage of cleaning the support by removing any traces of oxide, the powder particles sprayed at the beginning of the process acting like sanding of the surface of the support. The adhesion of the sprayed powder particles is therefore improved subsequently.

With such a method it is notably possible to remove the oxides present on aluminium supports, and thus deposit the first powder on an aluminium support in order to form an electric contact comprising an aluminium contact support.

According to a second alternative of the invention, the method for manufacturing an electric contact is such that the electric contact is made in two phases: one step for manufacturing the pad on a pad support, according to the method for manufacturing a pad, as described above, and a step for assembling the pad on a suitable electric contact support with view to its use as an electric contact.

In this alternative, the pad support may consist of a thin continuous strip of silver or copper (0.1-1 mm) which is used as a sublayer for brazing or welding. Deposition of the first powder by cold spray for forming the contact layer may take place directly on this strip. As described above, this strip may further undergo a final shaping operation, either by plastic deformation (rolling), or by removal of material (milling, planing, grinding), or possibly both. It is also possible to start with a brazing strip, and then add the different layers described above thereto. A multimetal strip is then obtained. The method may further comprise a step for cutting out said strip in order to form pads intended to be assembled with a conventional method (welding or brazing) for their use as an electric contact.

Moreover, the method for manufacturing an electric contact according to the invention may further comprise, prior to the step for depositing the contact layer, at least one step for applying at least one binding sublayer between the contact support and the contact layer.

Advantageously, said step for applying the binding sublayer is carried out by cold gas dynamic spraying of a second powder onto said contact support in order to form the binding sub layer, said second powder containing at least particles of a conducting metal compound.

The presence of such a binding sublayer is optional.

The binding sublayer may consist of a metal or of a metal alloy having hardness of the same order of magnitude as that of the support and relatively high electric conductivity, for example silver, a silver alloy with 5% copper or a solder based on silver.

Similarly, the method for manufacturing an electric pad according to the invention may further comprise prior to the step for depositing the contact layer, at least one step for applying by cold gas dynamic spraying, at least one second powder onto said pad support in order to form at least one binding sub layer between the pad support and the contact layer. In this case, the melting interval of the binding sublayer should be clearly higher than the solder possibly used subsequently for assembling the pad on the contact support.

Like for the first powder, the size of the particles of the second powder is comprised between 10 μm and 300 μm.

Moreover, the methods for manufacturing the pad or manufacturing the electric contact may further comprise, after the step for depositing the contact layer, at least one step for depositing by cold gas dynamic spraying, at least one third powder in order to form at least one overlayer, said third powder having a composition different from the first powder.

Like for the first and second powders, the size of the particles of the third powder is comprised between 10 μm and 300 μm.

More particularly, another advantage of the cold spray deposition method is to be able to modify the spraying nozzle, the composition of the powders used as well as the spray flow rates in order to obtain, above the contact layer, different layers which may correspond to different contact layers having different compositions. For example, it is possible to provide at the surface a layer suitable for weak currents, and another layer adapted to stronger currents underneath. Provision may also be made for depositing a protective overlayer for protecting the pad or the contact during storage, this overlayer being made in a material selected so as to be rapidly removed upon using the electric contact.

The following examples illustrate the present invention without however limiting the scope thereof.

### EXAMPLES

In Examples 1 to 3 described below, the model<<Kinetic 3000M>> made by Cold Gas technology (CGT) is used as a system for cold gas dynamic spraying. It comprises a control cabinet, a gas heater LINDSPRAY® Cold Spray Heater HT 800/30, a powder dispenser CGT-PF4000 Comfort, and a projection gun POWER-JET 3000.

### Example 1 (Comparative)

A mixture of silver powders is made for which the size is comprised between 30 and 80 microns and with a tin oxide for which the grains are smaller than 20 microns, the composition being 8% by weight of oxide (about 12% by volume).

Said mixture of powders was projected by cold spraying, at 30 bars and at 300° C. on a copper plate with a length of 50 mm with a width of 27 mm and a thickness of 1.5 mm. A 2 mm layer was deposited.
a. the porosity of the deposit did not exceed 3%.
b. the structure was macroscopically homogeneous, but microscopically heterogeneous
c. but the composition of the obtained layer did not correspond to the initial composition: there was a loss of oxide of about 50%.

### Example 2 (Invention)

A powder of tin oxide was coated with silver by CVD, in order to obtain the desired composition by volume (20%). The size of the grains was located between 10 and 40 microns. A layer of 1.5 mm was projected by cold spraying on precut copper and brass UZ15 supports (thickness 1.5 mm) under optimized conditions for this grain size. The conditions were 30 bars and 400° C.
a. the porosity of the deposit was low (<0.5%)
b. the structure was homogeneous
c. the composition of the obtained layer was that of the sprayed powder
d. however, expansion annealing showed cracking of the deposit, and
e. an electric test under AC3 conditions on a commercial apparatus (3×400 VAC, 37A) showed abnormally high erosion as compared with the standard material obtained by traditional powder metallurgy.

### Example 3 (Invention)

A spongeous powder of silver and tin oxide obtained via a chemical route (14% by weight of oxide, ˜20% by volume) according to the method described in patent U.S. Pat. No. 5,846,288 was projected by cold spraying at 30 bars and at 600° C., on preformed copper supports (deposited thickness: 3 mm, support: 4 mm). Its grain size was located between 40 and 300 microns.
a. the porosity of the deposit was less than 0.1%.
b. the structure was homogeneous
c. the composition of the obtained layer was that of the sprayed powder
d. an electric test under AC3 conditions (460 Amperes, 3×400 Volts) on a commercial apparatus showed that the lifetime was of the order of magnitude of that of usual contacts for this type of apparatus. Cracking at the end of life was reported, similar to that of the standard material but less deep.

### Example 4 (Invention)

Silver-refractory metal (nickel) contacts were elaborated by projection with cold spraying, according to the invention, on precut copper and brass UZ15 supports (thickness 1.5 mm). The conditions were 30 bars and 400° C.

The initial composition was 30% by mass (33.5% by volume) of nickel. The size of the nickel grains was located between 5 and 10 μm.
a. the nickel loss was between 25% and 50%
b. the structure is homogeneous microscopically, but nickel clusters of the order of 50 μm were observed.
c. the porosity of the deposit was limited to less than 1%
d. an electric test under AC3 conditions on a commercial apparatus showed erosion as being half less than that observed with the standard material usually fitting out this apparatus. The observed nickel clusters are not a nuisance insofar that no early adhesive bonding or contact resistance were observed.

### Example 5 (Comparative)

Silver-oxide refractory contacts of the same composition as those of Example 3, but elaborated by traditional powder metallurgy (compaction of billets, extrusion, rolling, cutting) were brazed on copper supports by induced current (HF welding).
a. the porosity was much less than 1% (extrusion)
b. the structure was homogeneous
c. the same electric test AC3 on apparatuses of the same type as those of Example 3 showed significant cracking as soon as the first third of their <<life>>.

1-23. (canceled)

24. A method for manufacturing at least one electric contact pad comprising a pad support and at least one contact layer, wherein it comprises a step for depositing, by cold gas dynamic spraying, a first powder onto said pad support in order to form said contact layer, said first powder containing at least particles comprising grains of at least one refractory material incorporated into a matrix based on a conducting metal selected from silver or copper.

25. The method according to claim 24, wherein the first powder further contains pure metal particles, corresponding to the conducting metal of the matrix containing the grains of refractory material.

26. The method according to claim 24, wherein the first powder further contains particles comprising grains of at least one first doping agent incorporated into a metal matrix, the metal of which corresponds to the conducting metal of the matrix containing the grains of refractory material.

27. The method according to claim 26, wherein the first doping agent is a metal or an oxide of this metal, said metal being selected from the group comprising Bi, Mo, W, Re, In and Cu.

28. The method according to claim 24, wherein at least one second doping agent is incorporated with grains of refractory material into their conducting metal matrix.

29. The method according to claim 28, wherein the second doping agent is a metal or an oxide of this metal, said metal being selected from the group comprising Bi, Mo, W, Re, In and Cu.

30. The method according to claim 24, wherein at least one third doping agent is introduced into the matrix containing the grains of refractory material.

31. The method according to claim 30, wherein the third doping agent is a metal or an oxide of this metal, said metal being selected from the group comprising Bi, Mo, W, Re, In and Cu.

32. The method according to claim 24, wherein the refractory material is selected from the group comprising CdO, CuO, SnO₂, ZnO, Bi₂O₃, C, WC, MgO, 1n₂O₃, as well as Ni, Fe, Mo, Zr, W or oxides thereof.

33. The method according to claim 24, wherein the first powder contains between 2% and 50% and preferably between 5% and 40% and more preferentially between 10% and 40% by volume of grains of refractory material based on the total volume of the first powder.

34. The method according to claim 24, wherein the particles comprising the grains of at least one refractory material incorporated into the conducting metal matrix are obtained from a method selected from the group comprising physical vapor deposition methods (PVD), chemical vapor deposition methods (CVD), electroless methods, chemical precipitation on suspended particles.

35. The method according to claim 24, wherein it further comprises, prior to the step for depositing the contact layer, at least one step for applying, by cold gas dynamic spraying, at least one second powder on said pad support in order to form at least one binding sublayer.

36. The method according to claim 35, wherein the size of the particles of the second powder is comprised between 10 μm and 300 μm.

37. The method according to claim 24, wherein it further comprises, after the step for depositing the contact layer, at least one step for depositing, by cold gas dynamic spraying, at least one third powder in order to form at least one overlayer, said third powder having a composition different from the first powder.

38. The method according to claim 37, wherein the size of the particles of the third powder is comprised between 10 μm and 300 μm.

39. The method according to claim 24, wherein the size of the particles of the first powder is comprised between 10 μm and 300 μm.

40. The method according to claim 24, wherein the pad support appears as a continuous strip, and in that said method further comprises a step for cutting out said strip in order to form electric contact pads.

41. A method for manufacturing at least one electric contact comprising a contact support and at least one electric contact pad comprising a pad support and at least one contact layer, wherein it comprises:
a step for manufacturing said electric contact pad with a method comprising a step for depositing, by cold gas dynamic spraying, a first powder onto said pad support in order to form said contact layer, said first powder containing at least particles comprising grains of at least one refractory material incorporated into a matrix based on a conducting metal selected from silver or copper, and
a step for assembling said electric contact pad onto said contact support.

42. The method according to claim 41, wherein the first powder further contains pure metal particles, corresponding to the conducting metal of the matrix containing the grains of refractory material.

43. The method according to claim 41, wherein the first powder further contains particles comprising grains of at least one first doping agent incorporated into a metal matrix, the metal of which corresponds to the conducting metal of the matrix containing the grains of refractory material.

44. The method according to claim 43, wherein the first doping agent is a metal or an oxide of this metal, said metal being selected from the group comprising Bi, Mo, W, Re, In and Cu.

45. The method according to claim 41, wherein at least one second doping agent is incorporated with grains of refractory material into their conducting metal matrix.

46. The method according to claim 45, wherein the second doping agent is a metal or an oxide of this metal, said metal being selected from the group comprising Bi, Mo, W, Re, In and Cu.

47. The method according to claim 41, wherein at least one third doping agent is introduced into the matrix containing the grains of refractory material.

48. The method according to claim 47, wherein the third doping agent is a metal or an oxide of this metal, said metal being selected from the group comprising Bi, Mo, W, Re, In and Cu.

49. The method according to claim 41, wherein the refractory material is selected from the group comprising CdO, CuO, SnO₂, ZnO, Bi₂O₃, C, WC, MgO, In₂O₃, as well as Ni, Fe, Mo, Zr, W or oxides thereof.

50. The method according to claim 41, wherein the first powder contains between 2% and 50% and preferably between 5% and 40% and more preferentially between 10% and 40% by volume of grains of refractory material based on the total volume of the first powder.

51. The method according to claim 41, wherein the particles comprising the grains of at least one refractory material incorporated into the conducting metal matrix are obtained from a method selected from the group comprising physical vapor deposition methods (PVD), chemical vapor deposition methods (CVD), electroless methods, chemical precipitation on suspended particles.

52. The method according to claim 41, wherein it further comprises, prior to the step for depositing the contact layer, at least one step for applying, by cold gas dynamic spraying, at least one second powder on said pad support in order to form at least one binding sublayer.

53. The method according to claim 52, wherein the size of the particles of the second powder is comprised between 10 μm and 300 μm.

54. The method according to claim 41, wherein it further comprises, after the step for depositing the contact layer, at least one step for depositing, by cold gas dynamic spraying, at least one third powder in order to form at least one overlayer, said third powder having a composition different from the first powder.

55. The method according to claim 54, wherein the size of the particles of the third powder is comprised between 10 μm and 300 μm.

56. The method according to claim 41, wherein the size of the particles of the first powder is comprised between 10 μm and 300 μm.

57. The method according to claim 41, wherein the pad support appears as a continuous strip, and in that said method further comprises a step for cutting out said strip in order to form electric contact pads.

58. A method for manufacturing at least one electric contact comprising a contact support and at least one contact layer, wherein it comprises a step for depositing, by cold gas dynamic spraying, a first powder onto said contact support in order to form said contact layer, said first powder containing at least particles comprising grains of at least one refractory material incorporated into a matrix based on a conducting metal selected from silver or copper.

59. The method according to claim 58, wherein the first powder further contains pure metal particles, corresponding to the conducting metal of the matrix containing the grains of refractory material.

60. The method according to claim 58, wherein the first powder further contains particles comprising grains of at least one first doping agent incorporated into a metal matrix, the metal of which corresponds to the conducting metal of the matrix containing the grains of refractory material.

61. The method according to claim 60, wherein the first doping agent is a metal or an oxide of this metal, said metal being selected from the group comprising Bi, Mo, W, Re, In and Cu.

62. The method according to claim 58, wherein at least one second doping agent is incorporated with grains of refractory material into their conducting metal matrix.

63. The method according to claim 62, wherein the second doping agent is a metal or an oxide of this metal, said metal being selected from the group comprising Bi, Mo, W, Re, In and Cu.

64. The method according to claim 58, wherein at least one third doping agent is introduced into the matrix containing the grains of refractory material.

65. The method according to claim 64, wherein the third doping agent is a metal or an oxide of this metal, said metal being selected from the group comprising Bi, Mo, W, Re, In and Cu.

66. The method according to claim 58, wherein the refractory material is selected from the group comprising CdO, CuO, SnO₂, ZnO, Bi₂O₃, C, WC, MgO, In₂O₃, as well as Ni, Fe, Mo, Zr, W or oxides thereof.

67. The method according to claim 58, wherein the first powder contains between 2% and 50% and preferably between 5% and 40% and more preferentially between 10% and 40% by volume of grains of refractory material based on the total volume of the first powder.

68. The method according to claim 58, wherein the particles comprising the grains of at least one refractory material incorporated into the conducting metal matrix are obtained from a method selected from the group comprising physical vapor deposition methods (PVD), chemical vapor deposition methods (CVD), electroless methods, chemical precipitation on suspended particles.

69. The method according to claim 58, wherein the contact support appears as precut individual parts.

70. The method according to claim 58, wherein the contact support appears as a continuous strip, and wherein said method further comprises a step for cutting out said strip in order to form electric contacts.

71. The method according to claim 70, wherein the contact layer forms on the strip, discrete contact points.

72. The method according to claim 70, wherein the contact layer forms on the strip, at least one continuous track.

73. The method according to claim 58, wherein the contact support is made in a material selected from the group comprising copper, aluminium, copper alloys, aluminium alloys and a steel-copper composite.

74. The method according to claim 58, wherein it further comprises prior to the step for depositing the contact layer, at least one step for applying by cold gas dynamic spraying, at least one second powder on said contact support in order to form at least one binding sublayer, said second powder containing at least particles of a conducting metal compound.

75. The method according to claim 74, wherein the size of the particles of the second powder is comprised between 10 μm and 300 μm.

76. The method according to claim 58, wherein it further comprises, after the step for depositing the contact layer, at least one step for depositing, by cold gas dynamic spraying, at least one third powder in order to form at least one overlayer, said third powder having a composition different from the first powder.

77. The method according to claim 76, wherein the size of the particles of the third powder is comprised between 10 μm and 300 μm.

78. The method according to claim 58, wherein the size of the particles of the first powder is comprised between 10 μm and 300 μm.

79. An electric contact comprising a contact support and at least one electric contact pad comprising a pad support and at least one contact layer, which is obtained according to a method comprising:
a step for manufacturing said electric contact pad with a method comprising a step for depositing, by cold gas dynamic spraying, a first powder onto said pad support in order to form said contact layer, said first powder containing at least particles comprising grains of at least one refractory material incorporated into a matrix based on a conducting metal selected from silver or copper, and
a step for assembling said electric contact pad onto said contact support.

80. An electric contact comprising a contact support and at least one contact layer which is obtained according to a method comprising a step for depositing, by cold gas dynamic spraying, a first powder onto said contact support in order to form said contact layer, said first powder containing at least particles comprising grains of at least one refractory material incorporated into a matrix based on a conducting metal selected from silver or copper.

81. An electric contact pad comprising a pad support and at least one contact layer, which is obtained by a method comprising a step for depositing, by cold gas dynamic spraying, a first powder onto said pad support in order to form said contact layer, said first powder containing at least particles comprising grains of at least one refractory material incorporated into a matrix based on a conducting metal selected from silver or copper.
